(19) United States
(12) Patent Application Publication
(10) Pub. No.: US 2023/0215702 A1
(43) Pub. Date: Jul. 6, 2023

(54) UNIFORMITY CONTROL FOR PLASMA PROCESSING USING WALL RECOMBINATION

(71) Applicant: Applied Materials, Inc., Santa Clara, CA (US)

(72) Inventors: Vladimir Nagorny, Tracy, CA (US); Rene George, Redwood City, CA (US); Wei Liu, San Jose, CA (US)

(21) Appl. No.: 17/566,584

(22) Filed: Dec. 30, 2021

(51) Int. Cl. H01J 37/32; H01L 21/66; G06N 3/08

(52) U.S. Cl. CPC H01J 37/32486; H01J 37/32467; H01L 22/20; G06N 3/08; H01J 2237/3387

(57) ABSTRACT

A system, method, and apparatus for processing substrates. A plasma processing system includes a processing chamber having a chamber body having walls with a first material enclosing an interior volume. The plasma processing system further includes a plasma source designed to expose a substrate disposed within the processing chamber to plasma related fluxes. The first material has a first set of recombination coefficients associated with the plasma related fluxes. The plasma processing system further includes a second material disposed along a first region of the chamber body, the first material having a second set of plasma recombination coefficients associated with the plasma related fluxes. The second set of plasma recombination coefficients is different that the first set of plasma recombination coefficients.

### TECHNICAL FIELD

The instant specification relates methods and systems for controlling plasma processing. Specifically, the instant specification relates to uniformity control for plasma processing using plasma species recombination on the walls (e.g., plasma radical wall recombination).

### BACKGROUND

Plasma processing is widely used in the semiconductor industry. Plasma can modify a chemistry of a processing gas (e.g., generating ions, radicals, etc.), creating new species, without limitations related to the process temperature, generating a flux of ions to the wafer with energies from a fraction of an electronvolt (eV) to thousands of eVs. There are many kinds of plasma sources (e.g., capacitively coupled plasma (CCP), inductively coupled plasma (ICP), microwave generated plasma, electron cyclotron resonance (ECR), and the like) that cover a wide operational process range from a few mTorr to a few Torr.

A common plasma process specification today is a high uniformity of the process result (e.g., a uniformity across a wafer up to the very edge of the wafer). For example, process uniformity requirement in today's semiconductor manufacturing may include requirements around 1%-2% across the whole wafer, with exclusion of 1-3 mm from the edge. These stringent constraints continuously get even firmer as researchers look for new methods for controlling process uniformity and/or finding improvements to existing methods for controlling process uniformity. Different uniformity controlling methods may be effective for some processes and completely useless for others.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In an exemplary embodiment, a plasma processing system includes a processing chamber including a chamber body having first wall material with a first set of recombination coefficients for a set of plasma species enclosing an interior volume. The plasma processing system further includes a plasma source designed to expose a substrate disposed within the processing chamber to plasma related fluxes. The plasma processing system may further include a second material disposed along a second region of the chamber body, the second material having a second set of recombination coefficients associated with the plasma related fluxes. The second set of plasma recombination coefficients is different from the first set of plasma recombination coefficients.

In an exemplary embodiment, a method includes obtaining a process result profile of a first substrate. The process result profile may include a plurality of thickness values of the first substrate measured after processing the first substrate in a processing chamber having a chamber body with walls having a first set of recombination coefficients. The method further includes determining that the process result profile comprises a first thickness value for a first location on the first substrate that deviates from a first reference thickness value. The method further includes determining a second material with a second set of plasma recombination coefficients different than the first set of plasma recombination coefficients and a second location along the chamber body proximate the first location on the first substrate. The method further includes determining the second material and the second location is responsive to determining that the first process result profile comprises the first thickness value that deviates from the reference thickness value. The method further includes processing a second substrate within the processing chamber with the second material disposed along the chamber body at the second location.

In an exemplary embodiment, a processing chamber apparatus includes a chamber body having walls with a first material enclosing an interior volume. The first material has a first set of plasma species recombination coefficients. The processing chamber apparatus further includes a second material disposed along a first region of the chamber body. The first material has second set of plasma recombination coefficients that are different than the first set of plasma recombination coefficients. The processing chamber apparatus further includes a third material disposed along a second region of the chamber body. The third material has a third set of plasma recombination coefficients that are different than the first set of plasma recombination coefficients and the second set of plasma recombination coefficients.

### BRIEF DESCRIPTION OF THE DRAWINGS

The present disclosure is illustrated by way of example, and not by way of limitation in the figures of the accompanying drawings.

FIG. 1 illustrates a processing system, according to aspects of the disclosure.

FIG. 2 illustrates a processing system with a chamber body having a surface material configuration, according to certain embodiments.

FIG. 3A illustrates a process result profile, according to certain embodiments.

FIG. 3B illustrates a process result profile, according to certain embodiments.

FIG. 4 is a top view of a substrate support structure, according to certain embodiments.

FIG. 5 illustrates is a bottom view of a chamber body within a processing chamber including a plasma injection site, according to certain embodiments.

FIG. 6 is a block diagram illustrating an exemplary system architecture in which implementations of the disclosure may operate.

FIG. 7 illustrates a model training workflow and a model application workflow for surface material configurations, in accordance with an embodiment of the present disclosure.

FIG. 8 depicts a flow diagram of one example method for predicting a recombination configuration for a processing chamber, in accordance with some implementations of the present disclosure.

FIG. 9 depicts a block diagram of an example computing device capable of plasma delivery and/or processing, operating in accordance with one or more aspects of the disclosure.

### DETAILED DESCRIPTION

A common plasma process parameter today is a high uniformity of a process result (e.g., a uniformity across a wafer up to the very edge of the wafer). This parameter is often very difficult to achieve, because it involves many factors, many of which interfere with others. Plasma uniformity, chamber design, wafer temperature distribution, design of the bias electrode, etc. are only part of those factors. Radio frequency (RF) antennas and processing chambers are manufactured and assembled to achieve the highest level of process uniformity.

One factor that affects process uniformity within a process chamber is wall recombination of radicals of a chamber body. Unless a recombination coefficient on the wall is a few percent or higher, conventional systems typically ignore the effects of wall recombination on plasma processing. For some processes, especially slow processes, wall recombination of reactive species plays a larger role than typically accounted for, even when recombination coefficients are much smaller than one percent. Manipulating surface material within a chamber body of a processing chamber can change a process profile by altering plasma recombination rates along a surface of the chamber body. For example, choosing materials for surfaces, placing liners, or other elements made of materials with selected properties, and/or using films, can have specific effects on portions of a process profile. Additionally, the location each of the materials are disposed within the chamber may affect different process results across a surface of a processed substrate. Since recombination coefficient of ions is constant (e.g., about 1), wall recombination may be effective for processes having large or main contribution from radicals that react with a substrate.

Aspects of the present disclosure provide for methods, systems, and apparatuses that allow for improved control of plasma processing within a processing chamber. For example, as described herein, methods, systems, and apparatuses leverage various materials having diverse sets of plasma recombination coefficients of the plasma radicals within a chamber to modify (e.g., correct for) deficiencies of a plasma process. For example, a first material may be placed proximate an edge of the substrate and improve process uniformity deficiencies occurring towards the edge region of the substrate. The present disclosure introduces a new processing chamber surface material configuration that includes, in some embodiments, actuators, couplers, or other devices for disposing materials with different plasma recombination rates to selectively modify plasma process results (e.g., to improve uniformity across a wafer). In some embodiments, the present disclosure identifies (e.g., using modeling techniques) materials and locations within a processing chamber to dispose the material to improve process results (e.g., more accurately meet process result requirements or reference process result profiles).

In an exemplary embodiment, a plasma processing system includes a processing chamber including a chamber body having walls with a first material having a first set of plasma recombination coefficients enclosing an interior volume. The plasma processing system further includes a plasma source designed to expose a substrate disposed within the processing chamber to plasma related fluxes. The first set of plasma recombination coefficients is associated with the plasma related fluxes. The plasma processing system may further include a second material disposed along a first region of the chamber body, the second material having a second set of plasma recombination coefficients associated with the plasma related fluxes. The second set of plasma recombination coefficients is different that the first set of plasma recombination coefficients.

In an exemplary embodiment, a method includes obtaining a process result profile of a first substrate. The process result profile may include a plurality of thickness values of the first substrate measured after processing the first substrate in a processing chamber having a chamber body with walls having a first material with a first set of plasma recombination coefficients. The method further includes determining that the process result profile comprises a first thickness value for a first location on the first substrate that deviates from a first reference thickness value. The method further includes determining a second material with a second set of plasma recombination coefficients different than the first set of plasma recombination coefficients and a second location along the chamber body proximate the first location on the first substrate. Determining the second material and the second location is responsive to determining that the first process result profile comprises the first thickness value that deviates from the first reference thickness value. The method further includes processing a second substrate within the processing chamber with the second material disposed along the chamber body at the second location.

In an exemplary embodiment, a processing chamber apparatus includes a chamber body having walls with a first material enclosing an interior volume. The processing chamber apparatus further includes a second material disposed along a first region of the chamber body. The first material has a second set of plasma recombination coefficients that is different than the first set of plasma recombination coefficients. The processing chamber apparatus further includes a third material disposed along a second region of the chamber body. The third material has a third set of plasma recombination coefficients that is different than the first set of plasma recombination coefficients and the second set of plasma recombination coefficients.

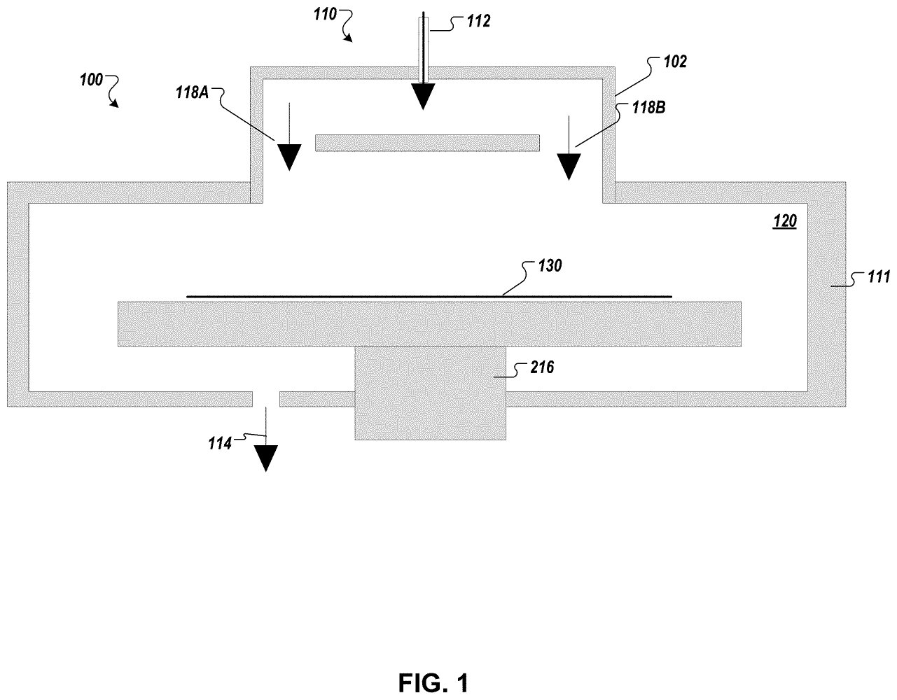

FIG. 1 illustrates a processing system 100, according to aspects of the disclosure. The processing system 100 may include a processing chamber 120 and a plasma source 110. A plasma source includes walls 102 (e.g., to hold the atmospheric pressure), a gas inlet 112, the gas distribution volume limited by the walls. Processing chamber 120 include walls 111 that holds inside vacuum and provides support to the plasma source 110, substrate support 116, and gas outlet 114. The gas inlet 112 and gas outlet 114 may provide a flow of feed gas through the processing system under processing gas pressure. The feed gas may comprise any of air, O₂, N₂, Ar, NH₃, He and/or other appropriate processing gases. Plasma source 110 may include a gas expansion volume of a gas injector (e.g. without plasma). The plasma source 110 may be designed to deliver plasma (e.g., generating or facilitating flow into) to a processing chamber 120. The plasma source delivers plasma through plasma injection sites 118A-B. The processing chamber 120 houses a substrate 130 to be processed by the processing system 100. The processing system 200 may be a plasma chamber including an etch chamber, deposition chamber (including atomic layer deposition, chemical vapor deposition, physical vapor deposition). For example, the plasma chamber may be a chamber for a plasma etcher, a plasma cleaner, and so forth.

In some embodiments, as shown in FIG. 1, the plasma may be injected into the processing chamber 120 through an annular opening (e.g., annular plasma injection site). In some embodiments, the processing system 100 may include other plasma injection configurations such as using a circular, linear, and/or other geometric opening. In another embodiment, the plasma may be injected into the processing chamber 120 using multiple plasma injection sites that each include one or more previously described geometric configurations or other configurations not described herein.

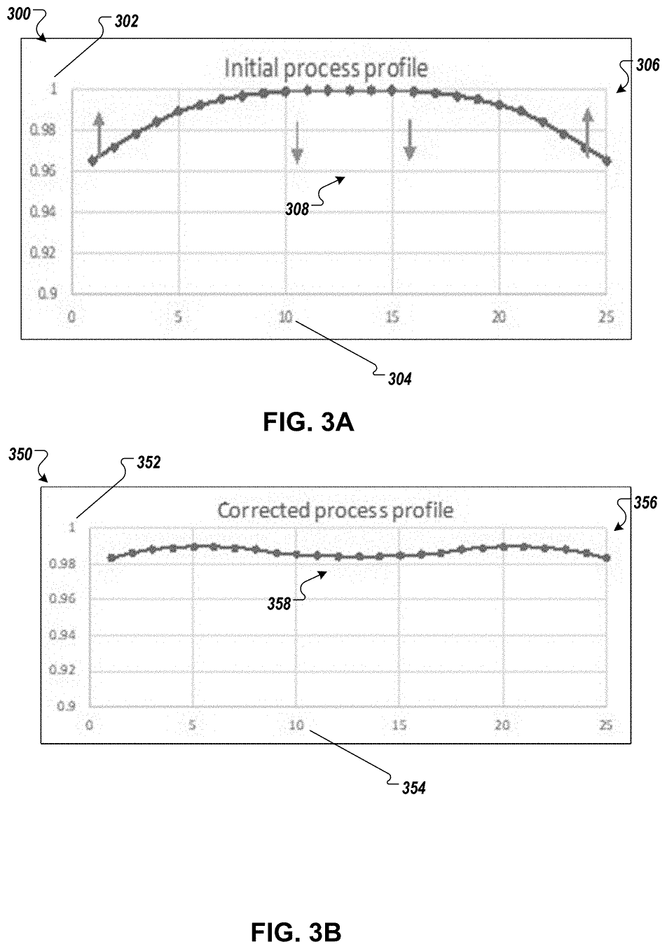

Processing system 100 includes a first surface material configuration. In some embodiments, the walls 111 of the processing system 100 have a material with a set of recombination coefficients that relates to a rate of reaction and combination of radicals (e.g., Nitrogen atoms N into nitrogen molecules N₂). In some embodiments the processing device may include one or more surface materials (e.g., liner, films, plates, etc.) having a set of recombination coefficients different than the walls 111. In some embodiments, processing system 100 includes an initial surface material configuration or an uncorrected surface material configuration that can be used to process a substrate and obtain (e.g., using substrate metrology) an initial process result profile (e.g. process result profile 300 of FIG. 3A). The initial process result may further be used to refine the process result profile (e.g., to improve process uniformity) by updating the initial surface material configuration to a corrected or updated surface material configuration (e.g., adding surface materials, locating or relocating surface materials, etc.). The processing system 100 may further be used to process a new substrate to obtain (e.g., using substrate metrology) an updated process result profile.

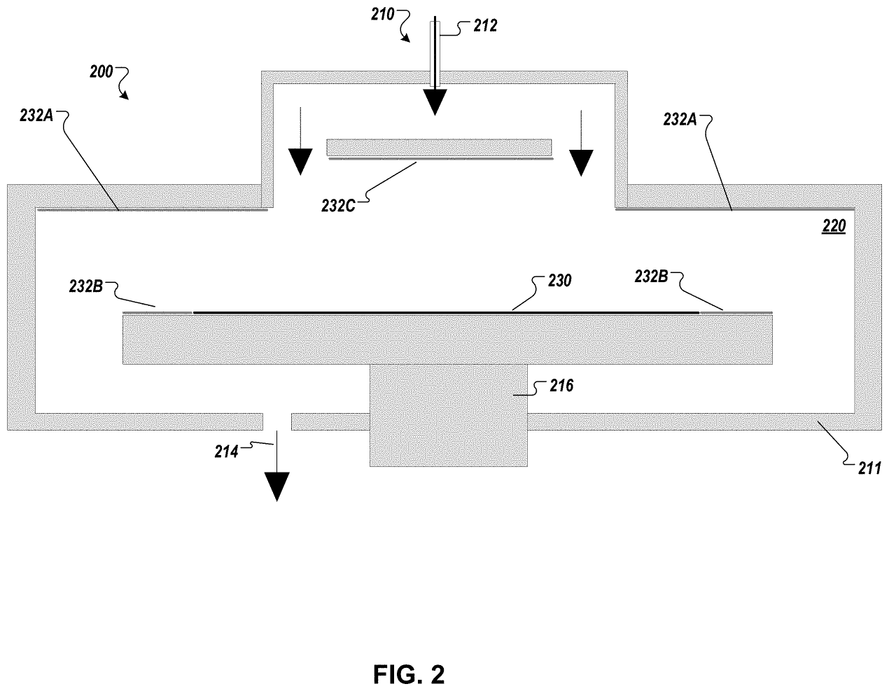

FIG. 2 illustrates a processing system 200 with a chamber body having a surface material configuration, according to certain embodiments. The processing system 200 may include a processing chamber 220 and a plasma source 210. A plasma source includes walls 202 (e.g., to hold the atmospheric pressure), a gas inlet 212, the gas distribution volume limited by the walls. Processing chamber 220 include walls 211 that hold inside vacuum and provide support to the plasma source 210, substrate support 216, and gas outlet 214 and may include features described in association with processing chamber in other embodiments. The gas inlet 212 and gas outlet 214 may provide a flow of feed gas through the processing system under the processing gas pressure. The feed gas may comprise any of air, O₂, N₂, Ar, NH₃, He and/or other appropriate processing gases. Plasma source 210 may include a gas expansion volume of a gas injector (e.g. without plasma). The plasma source 210 is designed to deliver plasma (e.g., generating or facilitating flow into) the processing chamber 220 and process a substrate 230 disposed within the processing chamber 220.

In some embodiments, as shown in FIG. 2, the plasma may be injected into the processing chamber 220 through an annulus opening. In some embodiments, the processing system 200 may include other plasma injection configurations such as using a circular, linear, and/or other geometric opening. In another embodiment, the plasma may be injected into the processing chamber 220 using multiple plasma injection sites that each include one or more previously described geometric configurations or other configurations not described herein.

As shown in FIG. 2, processing system 200 includes a surface material configuration. In some embodiments, the walls 211 of the processing chamber 220 may include a material having a recombination coefficient that relates to a rate of reaction and combination of radicals (e.g., Nitrogen atoms N into nitrogen molecules N₂). In some embodiments the processing device may include one or more surface materials 232A-C (e.g., liners, films, plates, etc.) of a material having a recombination coefficient different than the walls 211.

Surface materials may include liners or other elements made of material with selected properties (e.g., associated with a set of plasma species recombination rates or coefficients). In some embodiments, the material may be disposed on the chamber body (e.g., as a film). The surface materials may have a first set of plasma recombination coefficients (e.g., each associated with various plasma species). A plasma recombination coefficient may include a rate at which a reactive species of a plasma combine or interact at or near a surface of the chamber body 220. The plasma recombination coefficients may correspond with plasma or plasma related fluxes generated by plasma source 210.

For many processes, especially slow processes (e.g., processing having a process result rate below a threshold amount of time or whose total process or individual process procedures (e.g., process steps) include a processing duration beyond a threshold duration of time), wall recombination of reactive species plays a larger role, even when recombination coefficients are much small than one percent. Thus, manipulating the material of the surfaces of a chamber body of a processing chamber can change a process profile. For example choosing materials for surfaces, placing liners, or other elements made of materials with selected properties, or using films, can have specific effects on portions of a process profile. Additionally, the location at which each of the materials is disposed within the chamber may affect different process results across a surface of a processed substrate.

As shown in FIG. 2, the processing chamber 220 may include a first surface material 232A disposed along the walls 211 of a body of the processing chamber 220. The first surface material 232A may include a material with a first set of recombination rates (e.g., recombination coefficients) that are lower than that of the walls 211. The processing chamber 220 may include a second surface material 232B with a set of recombination rates (e.g., recombination coefficients) that are lower than that of the walls 211. The processing chamber may include a third surface material that may include a material with a recombination rate (e.g., a set of recombination coefficients) that is greater than that of the walls. The surface material configuration illustrated in FIG. 2 is purely exemplary and illustrates exemplary locations the surface materials 232A-C may be distributed within the processing chamber.

In some embodiments, surface materials 232A-C that are disposed proximate a region of the substrate 230 and can affect a localized process result of the substrate proximate the surface materials. For example, as shown in FIG. 2, surface materials 232A and 232B are disposed within the processing chamber 220 at locations proximate the edge of substrate 230. Surface materials 232A-B influence the process result of the edge region of the substrate based on the relative recombination of the material. For example, in embodiments where surface materials 232A-B have one or more higher recombination coefficients than corresponding recombination of materials of the walls 211, the addition of the surface materials 232A-B raises the process result near the edge of the substrate 230 when processed within the processing chamber 220. In another example, in embodiments where surface materials 232A-B have one or more recombination coefficients lower than that of the material of the walls 211, the addition of surface material 232A-B lowers the process result near the edge of the substrate 230 when processed in the processing chamber 220.

In another example, surface material 232C is disposed along the walls 211 at a location proximate a central region of substrate 330 and can affect the process result of substrate 230 at and/or near the center of the substrate. For example, in embodiments where surface material 232C has higher recombination coefficients than the material of the walls 211 (e.g., and/or support structure 216) the addition of the surface material 232C raises the process result near the center of the substrate 230 processed within the processing chamber 230. In another example, in embodiments where surface material 232C has lower recombination coefficients than the material of the walls 211 (e.g., and/or support structure 216), the addition of the surface material 232 lowers the process result near the center of the substrate 230 when processed in the processing chamber 220.

In some embodiments, the surface materials may be moveable within the process chamber. For example, the processing chamber may include an actuator that couples to the surface material(s) 232A-C. The surface material(s) 232A-C may be coupled to the walls 211 and be disposed a distance from the walls 211. The actuator may be leveraged to alter the distance between the surface material(s) 232A-C. For example, the surface material may be couple to a translatable platform affixed (e.g., fastened and/or adhered) to walls 211. The actuator may translate the surface materials to be closer or further away from the substrate. For example, surface material 232A and 232C may translate to be lowered or raised to be closer or further from the substrate 230. In some embodiments the surface material(s) 232A-C are substantially parallel to one or more of walls 211.

In some embodiments the substrate support structure 216 may be capable of moving (e.g., translating) to move the substrate closer to one or more surface materials 232A-C. For example, the substrate support structure 216 may translate up or down to raise or the lower the substrate and increasing or reducing the distance between the substrate and the surface materials.

In some embodiments, in addition to or alternative to surface material deployed using liners and/or films, the surface material may be deployed within the processing chamber as a foldable diaphragm structure. The foldable diaphragm structure may include multiple movable intercepting panels or leaves that can alter its shape (e.g., increase/decrease exposed surface area), resulting in a larger or smaller influence on a process result of a region proximate the foldable diaphragm. In some embodiments, the processing chamber includes a mechanism (e.g., translation plate, rotating plate, etc.) for altering a position of the foldable diaphragm structure within the processing chamber. In some embodiments, the surface materials may be disposed on moveable plates and/or structures capable of relocating the surface materials within the chambers. For example, the surface materials may be disposed on a rotatable wall or translation plate.

In some embodiments, the processing chamber includes mechanisms for heating and/or cooling the surface materials 232A-C within the processing chamber. The heating and/or cooling of the surface materials 232A-C may modify one or more associated recombination coefficients of the surface material. The heating and/or cooling may extend a usable range of recombination coefficients (e.g., without changing manufacturing equipment).

In some embodiments, the chamber body includes walls 211 having a first material with a first set of plasma recombination coefficients (e.g., for various plasma species), and one or more of the surface materials 232A-C having a second set of plasma recombination coefficients. Surface materials 232A-C may include a second set of plasma recombination coefficients in a first region within the chamber body and a third set of plasma recombination coefficients in a second region within the chamber body. In some embodiments, more than two combinations of materials having a variety of recombination coefficients may be leveraged throughout the inner volume along the chamber body. In some embodiments, surface materials 232A-C may be disposed along or proximate the substrate support assembly 216.

In some embodiments, the recombination coefficients of the surface materials 232A-C and/or materials of walls 211 of the chamber body may be associated with silicon nitridation occurring within the process chamber 220. Silicon nitridation uses nitrogen atoms N (radicals), usually obtained in plasma discharge by dissociation of a nitrogen molecule N₂. The nitridation can be a slow process, so the radical flux on the wafer and it profile can be completely defined by faster processes such as radicals generation, radicals flow from the generation region (e.g., plasma source 210) to the exhaust (e.g., exhaust port 214), and the radicals diffusion to the walls (including substrate) and recombination on the walls. Placing materials (e.g., surface materials 232A-C) in regions (e.g., along a surface of chamber body) with high or low recombination rates of certain plasma species can alter the localized recombination rate of the radicals (e.g., of various plasma species) and result in a processed substrate with improved uniformity (e.g., a substrate with less deviation of a process result such as film thickness across a surface of the substrate).

In some embodiments, portions of walls 211 of chamber body may include regions or portions of a surface having materials with high recombination rates and/or low recombination rates for various plasma species. A first surface material 232A with a material having a low recombination coefficient (e.g., a good reflector of radicals, a value less than the walls 211 of chamber body) may be disposed near a region or regions on the substrate with process values (e.g. film thickness, critical dimension, etc.) that are below a reference process result (e.g., desired thickness or process result uniformity). For example, if the process profile (e.g., thickness profile) of a substrate processed in a manufacturing chamber with quartz walls had a process result having a relatively higher (e.g., thicker) central region and a lower (e.g., thinner) edge region, a surface material having a low recombination rate may be disposed to cover the walls (e.g., liner, film, etc.) near the wafer edge. Examples of such materials having low combination rates include Pyrex or other borosilicate glass, Boron nitride films, and so on. For example, Pyrex, borosilicate clades, and boron nitride films may have recombination coefficients for nitrogen that are 3-10 times lower than the recombination coefficient of quartz, which is often used for chamber walls. A different material such as Titanium or stainless steel, which has recombination coefficients for nitrogen 3-10 times higher than quartz, may be disposed near the center of the wafer to reduce process results (e.g., thickness) near the center.

In some embodiments, plasma and flow simulations may be used to determine dimensions and positions of the surface materials 232A-C to setup a manufacturing chamber 100 to process a substrate that results in a process profile having higher process uniformity rating than alternative surface material configurations and/or absent surface materials 126. Surface materials 128 may include disks, rings, coatings, films, and/or other components in embodiments.

FIG. 3A illustrates a process result profile 300, according to certain embodiments. The process result profile may include an initial process profile or uncorrected process result profile (e.g., using a surface material configuration shown in FIG. 1 and discussed in the corresponding description) of a substrate processed within a processing system (e.g., plasma source, processing chamber, etc.). The process result profile may depict a process result parameter (e.g., thickness, critical dimension, etc.). A first axis 304 is associated with a location across a surface of the wafer. For example, the process profile may be measured across a radial direction from a first edge to a second edge and that travels proximately through a center of the substrate. A second axis 302 indicates the process result values (e.g., thickness values). In some embodiments, the values may be normalized or otherwise show a relative value (e.g., percentages of the largest value) of a process result in relation to another value or reference value.

The process result profile 300 may indicate portions of the process result that are greater (e.g., thicker) and/or less (e.g., thinner) than threshold process result values (e.g., average process result values, process control limits, statistical values such as deviation or variance, etc.). For example, a first region 308 of the process result profile 300 represents a region on the surface of the substrate (e.g., the center of the substrate). As shown in FIG. 3A, the process result profile 300 indicates that the first region 308 includes process result values that are greater than the average process result. The values within first region 308 can be reduced to lessen variance between other process result values of other regions of the substrate (e.g., to improve process uniformity). A second region 306 of the process result profile 300 represents a region on the surface of the substrate (e.g., an edge of the substrate). As shown in FIG. 3A, the process result profile 300 indicates that the second region 306 includes process result values that are less than the average process result. The values within second region 306 can be increased to lessen variance between other process result values of other regions of the substrate (e.g., to improve process uniformity).

As is discussed further in embodiments, different surface material configurations (e.g., materials of different sets of recombination coefficients disposed at various locations within a processing chamber) can be deployed during substrate processing and can affect the processing results (e.g., thickness) across a surface of a substrate. For example, different surface material configurations can increase process results of the second region 306 and reduce the process result values of the first region 308, as shown in FIG. 3A (e.g., to improve process uniformity).

FIG. 3B illustrates a process result profile 350, according to certain embodiments. The process result profile may include and modified process profile or corrected process result profile (e.g., using a surface material configuration shown in FIG. 2 and discussed in the corresponding description) of a substrate processed within a processing system (e.g., plasma source, processing chamber, etc.). The process result profile may depict a process result parameter (e.g., thickness, critical dimension, etc.). A first axis 354 is associated with location across a surface of the wafer. For example, the process profile may be taken across a radial direction from a first edge to a second edge and may travel proximate a center of the substrate. A second axis 352 indicates the process result values (e.g., thickness values). In some embodiments, the values may be normalized or otherwise show a relative value (e.g., percentages of the largest value) of a process result in relation to another value or reference value. Process result profile 350 may include one or more features and/or aspects of process result profile 250.

As is discussed further in other embodiments, different surface material configurations (e.g., materials of different sets of recombination coefficients disposed at various locations within a processing chamber) can be employed during substrate processing and can affect the processing results values of a substrate. For example, comparing process result profile 350 to process result profile 250 of FIG. 2B, different surface material configurations can increase process result values such of the second region 256 to an updated second region 356 and reduce the process result values of the first region 258 to an updated first region 358. The following corrections may occur responsive to using a surface material configuration as shown a described in association with FIG. 2. Process result profiles 250 and 350 are merely but are used to illustrate how recombination configuration (e.g., disposition of materials with varying recombination rates) within a chamber can be updated to process a substrate resulting in a generally more uniform process result.

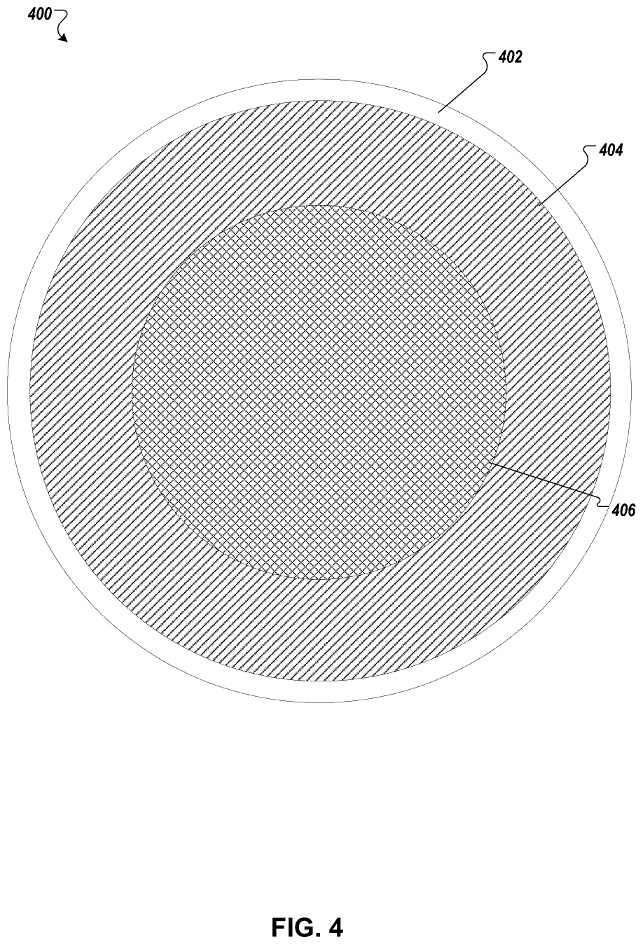

FIG. 4 is a top view of a substrate support structure 400, according to certain embodiments. As shown in FIG. 4, the substrate support structure 400 may include a support surface 402. The support surface 402 may include a first material having a first set of recombination coefficients (e.g., the same as walls 211 and 311 of FIGS. 2 and 3, respectively). The substrate support structure 400 supports a substrate 406. The substrate support structure further includes a surface material 404. The surface material 404 may include one or more features and/or aspects of surface materials 332A-C. The surface material 404 may have a second set of recombination rates that is different from the first set of recombination rates of the support surface 402. The substrate 406 and the surface material 404 are disposed on the support surface 402.

In some embodiments, the surface material 404 is disposed as a single disk with a hollowed center designed to fit the substrate 406. In some embodiments, the surface material 404 is disposed as multiple disks or rings. For example, the surface material 404 may be disposed as concentric rings centered about the center of the substrate 406. Generally the surface material 404 is disposed in a region between the edge of the support surface 402 and the edge of the substrate 406. In some embodiments, the surface material 404 is disposed up to the edge of the support surface 402 and/or up to the edge of the substrate 406, in other embodiments, the surface material 404 is disposed such there is a gap between an outer edge of the surface material 404 and the edge of the support surface 402 and/or a gap between the edge of the substrate 406 and an inner edge of the surface material 404.

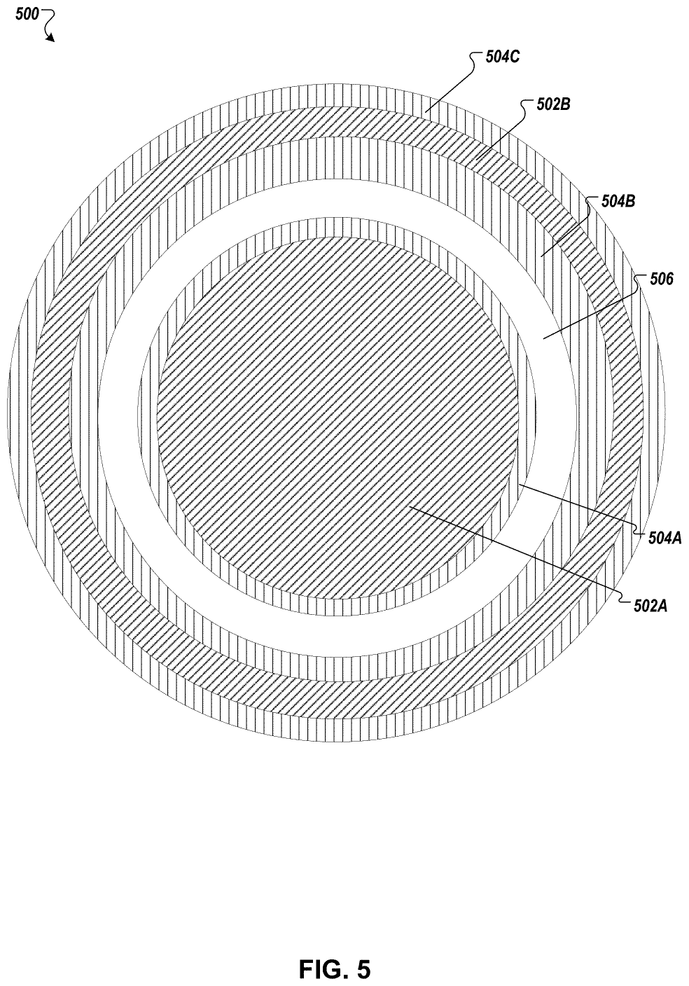

FIG. 5 illustrates is a bottom view of a chamber body 500 within a processing chamber including a plasma injection site 504, according to certain embodiments. As shown in FIG. 5, the chamber body 500 includes a wall structure 504A-C, surface material 502A-B, and plasma injection site 506. The wall structures 504A-C may include a first material having a first set of recombination coefficients. The wall structure 504A-C forms an opening to create plasma injection site 506. The plasma injection site 506 is designed to deliver plasma (e.g., facilitating flow into) to a processing chamber. In some embodiments, the plasma injection site 506 may include an annulus opening. In some embodiments, the chamber body 500 may include other plasma injection configurations such as using a circular, linear, and/or other geometric opening. In another embodiment, the plasma may be injected into the processing chamber using multiple plasma injection sites that each include one or more previously described geometric configurations or other configurations not described herein.

In some embodiments, the chamber body 500 includes a first surface material 502A disposed along a first region of the chamber body 500 along wall structure 504A located within the plasma between the opening of the plasma injection site 506. In some embodiments, the first surface material 502A is disposed in a circle configuration, in other embodiments, the first surface material 502A is disposed in a set of concentric rings or disks. In some embodiments, the surface material 502A covers the entirety of the first region of the chamber body 500 (e.g., abuts an edge of the plasma injection site).

In some embodiments, the chamber includes a second region disposed between walls structures 504B-C. The second region may be disposed outside a radius or outer perimeter of the plasma injection site 506 to an edge of the chamber body 500. The chamber body may include a second surface material 502B disposed within the second region along wall structures 504B-C. The second surface material 502B may have a first set of recombination coefficients different that the wall structure 504A-C. In some embodiments, the first surface material 502A has the same recombination coefficients as second surface material 502B. In some embodiments, one or both of the set of recombination coefficients of the first surface material 502A or the second surface material 502B may be greater or less than corresponding recombination coefficients of material of wall structures 504A-C.

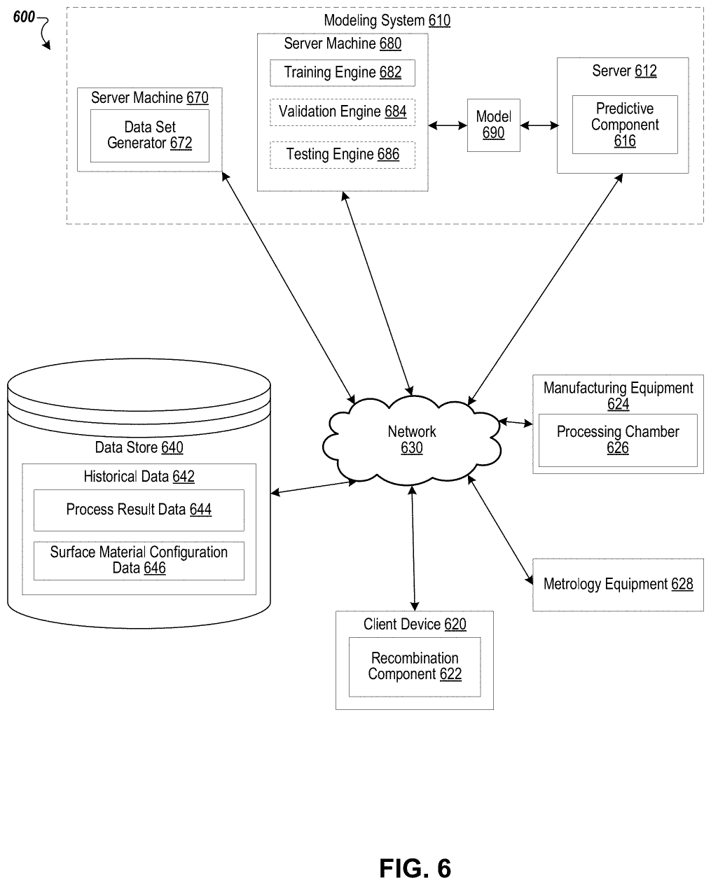

FIG. 6 is a block diagram illustrating an exemplary system architecture 600 in which implementations of the disclosure may operate. The manufacturing chamber 100 includes a client device 620, manufacturing equipment 624, metrology equipment 628, a server 612, and a data store 640. The server 612 may be part of a modeling system 610. The modeling system 610 may further include server machines 670 and 680.

Manufacturing equipment 624 (e.g., associated with producing, by manufacturing equipment 624, corresponding products, such as wafers) may include one or more processing chambers 626.

The client device 620, manufacturing equipment 624, metrology equipment 628, server 612, data store 640, server machine 670, and server machine 680 may be coupled to each other via a network 630 for modeling plasma recombination and determining recombination configurations (e.g., for improving process uniformity of substrate processing within processing chambers 626).

In some embodiments, network 630 is a public network that provides client device 620 with access to the server 612, data store 640, and/or other publically available computing devices. In some embodiments, network 630 is a private network that provides client device 620 access to manufacturing equipment 624, metrology equipment 628, data store 640, and/or other privately available computing devices. Network 630 may include one or more Wide Area Networks (WANs), Local Area Networks (LANs), wired networks (e.g., Ethernet network), wireless networks (e.g., an 802.11 network or a Wi-Fi network), cellular networks (e.g., a Long Term Evolution (LTE) network), routers, hubs, switches, server computers, cloud computing networks, and/or a combination thereof.

The client device 620 may include a computing device such as Personal Computers (PCs), laptops, mobile phones, smart phones, tablet computers, netbook computers, network connected televisions (“smart TV”), network-connected media players (e.g., Blu-ray player), a set-top-box, Over-the-Top (OTT) streaming devices, operator boxes, etc. The client device 620 may include a recombination component 622. Recombination component 622 may receive data from metrology equipment 628 such as process result data and displays the process result data on the client device (e.g., in the form of process result profiles (e.g., process result profile 250, 350 of FIG. 2B and FIG. 3B, respectively). The recombination component 622 may interact with one or more element of modeling system 610 to determine one or more configurations of surface material (e.g., materials with varying sets of recombination coefficients and locations the materials are to be disposed) to be disposed within processing chamber 626 to process a substrate that meets threshold criteria (e.g., process uniformity requirements).

Data store 640 may be a memory (e.g., random access memory), a drive (e.g., a hard drive, a flash drive), a database system, or another type of component or device capable of storing data. Data store 640 may store one or more historical data 642 including process result data 644 and/or surface material configuration data 646. In some embodiments, the historical data 642 may be used to train, validate, and/or test a machine learning model 690 of modeling system 610.

Modeling system 610 may include one or more computing devices such as a rackmount server, a router computer, a server computer, a personal computer, a mainframe computer, a laptop computer, a tablet computer, a desktop computer, etc. In some embodiments, modeling system 610 may include a predictive component 616. Predictive component 616 may take data retrieved metrology equipment 628 to generate recombination configuration data. The predictive component receives metrology data from metrology equipment 628. The metrology data may include a process result profile associated with a substrate processed in processing chamber 626. The predictive component determines (e.g., using model 690) a recombination configuration. The recombination configuration may include one or more materials having a set of recombination coefficients disposed at determine locations within the processing chamber 626. For example, a substrate processed in a processing chamber with surface materials disposed according to the recombination configuration result in a processed substrate having processed result meeting threshold criteria (e.g., process uniformity requirements).

In some embodiments, the predictive component 616 may use historical data 642 to determine a recombination configuration that when applied to a processing chamber results in a substrate processed in the chamber that meet threshold criteria (e.g. process uniformity requirements). In some embodiments, the predictive component 616 may use a model 690 (e.g. trained machine learning model) to identify recombination configurations when utilized by a processing chamber result in a substrate with process results meeting a threshold condition (e.g., process uniformity requirements). The model 190 may use historical data to determine the recombination configurations.

In some embodiments, the modeling system 610 further includes server machine 670 and server machine 680. The server machine 670 and 680 may be one or more computing devices (such as a rackmount server, a router computer, a server computer, a personal computer, a mainframe computer, a laptop computer, a tablet computer, a desktop computer, etc.), data stores (e.g., hard disks, memories databases), networks, software components, or hardware components.

Server machine 670 may include a data set generator 672 that is capable of generating data sets (e.g., a set of data inputs and a set of target outputs) to train, validate, or test a machine learning model.

Server machine 680 includes a training engine 682, a validation engine 684, and a testing engine 686. The training engine 182 may be capable of training a model 690 (e.g., machine learning model) using one or more process result data 644 and surface material configuration data 646. The validation engine 184 may determine an accuracy of each of models 690 based on a corresponding set of features of each training set. The validation engine 184 may discard models 690 that have an accuracy that does not meet a threshold accuracy. The testing engine 186 may determine a model 690 that has the highest accuracy of all of the trained machine learning models based on the testing (and, optionally, validation) sets.

In some embodiments, the training data is provided to train the model 690 such that the trained machine learning model is to receive a new input having new metrology data comprising a process result profile and to produce a new output based on the new input, the new output indicating a new recombination configuration, wherein the new recombination configuration indicates at least a new surface material (e.g., having a recombination coefficient) and location within a process chamber the new material is to be disposed such that a processing chamber processing a substrate with the new recombination configuration produce a substrate with a substrate meeting threshold criteria (e.g., process uniformity requirements).

The model 690 may refer to the model that is created by the training engine 182 using a training set that includes data inputs and corresponding target output (historical results of cell cultures under parameters associated with the target inputs). Patterns in the data sets can be found that map the data input to the target output (e.g. identifying connections between portions of the cell growth data and resulting yield of the target product formation), and the machine learning model 690 is provided mappings that captures these patterns. The machine learning model 690 may use one or more of logistic regression, syntax analysis, decision tree, or support vector machine (SVM). The machine learning may be composed of a single level of linear of non-linear operations (e.g., SVM) and/or may be a neural network.

The confidence data may include or indicate a level of confidence of one or more recombination configurations that when a substrate process a substrates according to the recombination configuration will result in a substrate having process results that meets threshold criteria (e.g., process uniformity requirements). In one non-limiting example, the level of confidence is a real number between 0 and 1 inclusive, where 0 indicates no confidence of the one or more prescriptive actions and 1 represents absolute confidence in the prescriptive action.

For purpose of illustration, rather than limitation, aspects of the disclosure describe the training of a machine learning model and use of a trained learning model using information pertaining to historical data 642. In other implementation, a heuristic model or rule-based model is used to determine a prescriptive action. In some embodiments, model 690 including physics-based element or derive prediction through physics-based principles. For example, model 690 may include a physics-based model based on plasma and flow equations, principles, and/or simulations.

In some embodiments, the functions of client devices 620, server 612, data store 640, and modeling system 610 may be provided by a fewer number of machines than shown in FIG. 6. For example, in some embodiments, server machines 670 and 680 may be integrated into a single machine, while in some other embodiments, server machine 670 and 680 and server 612 may be integrated into a single machine.

In general, functions described in one embodiment as being performed by client device 620, data store 640, metrology system 628, manufacturing equipment 624, and modeling system 610 can also be performed on server 612 in other embodiments, if appropriate. In addition, the functionality attributed to a particular component can be performed by different or multiple components operating together.

In embodiments, a “user” may be represented as a single individual. However, other embodiments of the disclosure encompass a “user” being an entity controlled by multiple users and/or an automated source. For example, a set of individual users federated as a group of administrators may be considered a “user.”

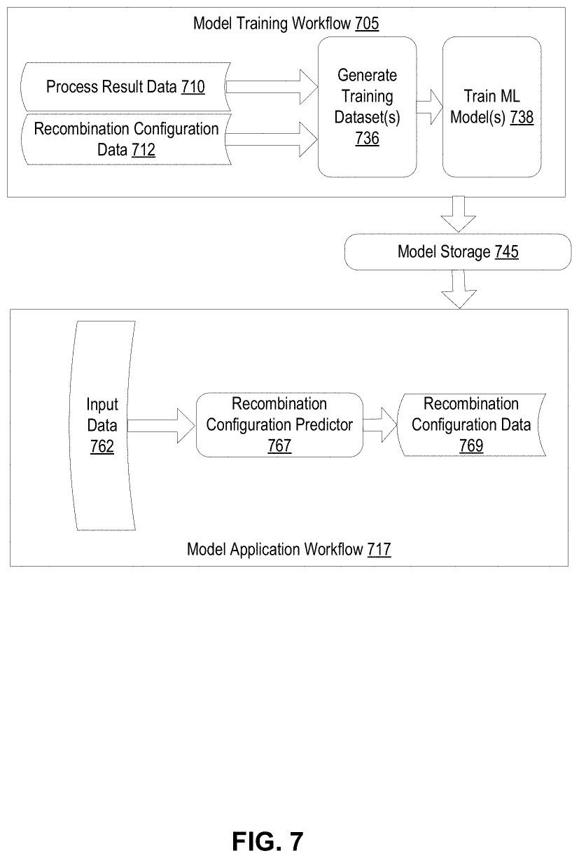

FIG. 7 illustrates a model training workflow 705 and a model application workflow 717 for surface material configurations (e.g., plasma recombination configurations), in accordance with an embodiment of the present disclosure. In embodiments, the model training workflow 705 may be performed at a server which may or may not include a recombination configuration application, and the trained models are provided to a recombination configuration application (e.g., on client device 620 of FIG. 6), which may perform the model application workflow 717. The model training workflow 705 and the model application workflow 717 may be performed by processing logic executed by a processor of a computing device. One or more of these workflows 705, 717 may be implemented, for example, by one or more machine learning modules implemented by server 612 of FIG. 6.

The model training workflow 705 is to train one or more machine learning models (e.g., deep learning models) to perform one or more classifying, segmenting, detection, recognition, decision, etc. tasks associated with a recombination configuration predictor. The model application workflow 717 is to apply the one or more trained machine learning models to perform the classifying, segmenting, detection, recognition, determining, etc. tasks for identifying configuration of surface materials (e.g., plasma recombination configurations). One or more of the machine learning models may receive and process result data (e.g., metrology data of processed wafers) and recombination configuration data.

Various machine learning outputs are described herein. Particular numbers and arrangements of machine learning models are described and shown. However, it should be understood that the number and type of machine learning models that are used and the arrangement of such machine learning models can be modified to achieve the same or similar end results. Accordingly, the arrangements of machine learning models that are described and shown are merely examples and should not be construed as limiting.

In embodiments, one or more machine learning models are trained to perform one or more of the below tasks. Each task may be performed by a separate machine learning model. Alternatively, a single machine learning model may perform each of the tasks or a subset of the tasks. Additionally, or alternatively, different machine learning models may be trained to perform different combinations of the tasks. In an example, one or a few machine learning models may be trained, where the trained ML model is a single shared neural network that has multiple shared layers and multiple higher level distinct output layers, where each of the output layers outputs a different prediction, classification, identification, etc. The tasks that the one or more trained machine learning models may be trained to perform are as follows:
1. Recombination configuration predictor—As discussed previously, relationships between plasma recombination configuration (e.g., dispositions of surface materials disposed along a surface of a chamber body at determined location with determine plasma recombination configuration) may be employed to predict recombination configurations that when utilized within a processing chamber result in substrate processed within the processing chamber having process results that meet a threshold criteria (e.g., process uniformity requirements). The recombination configuration predictor receives data indicative of a process result profile and outputs a first material with a first set of plasma recombination coefficients and a first location along a chamber body proximate a corresponding location on the first substrate.

One type of machine learning model that may be used to perform some or all of the above tasks is an artificial neural network, such as a deep neural network. Artificial neural networks generally include a feature representation component with a classifier or regression layers that map features to a desired output space. A convolutional neural network (CNN), for example, hosts multiple layers of convolutional filters. Pooling is performed, and non-linearities may be addressed, at lower layers, on top of which a multi-layer perceptron is commonly appended, mapping top layer features extracted by the convolutional layers to decisions (e.g. classification outputs). Deep learning is a class of machine learning algorithms that use a cascade of multiple layers of nonlinear processing units for feature extraction and transformation. Each successive layer uses the output from the previous layer as input. Deep neural networks may learn in a supervised (e.g., classification) and/or unsupervised (e.g., pattern analysis) manner. Deep neural networks include a hierarchy of layers, where the different layers learn different levels of representations that correspond to different levels of abstraction. In deep learning, each level learns to transform its input data into a slightly more abstract and composite representation. Notably, a deep learning process can learn which features to optimally place in which level on its own. The “deep” in “deep learning” refers to the number of layers through which the data is transformed. More precisely, deep learning systems have a substantial credit assignment path (CAP) depth. The CAP is the chain of transformations from input to output. CAPs describe potentially causal connections between input and output. For a feedforward neural network, the depth of the CAPs may be that of the network and may be the number of hidden layers plus one. For recurrent neural networks, in which a signal may propagate through a layer more than once, the CAP depth is potentially unlimited.

Training of a neural network may be achieved in a supervised learning manner, which involves feeding a training dataset consisting of labeled inputs through the network, observing its outputs, defining an error (by measuring the difference between the outputs and the label values), and using techniques such as deep gradient descent and backpropagation to tune the weights of the network across all its layers and nodes such that the error is minimized. In many applications, repeating this process across the many labeled inputs in the training dataset yields a network that can produce correct output when presented with inputs that are different than the ones present in the training dataset.

For the model training workflow 705, a training dataset containing hundreds, thousands, tens of thousands, hundreds of thousands or more process result data 710 (e.g., process result profiles, thickness profiles) should be used to form a training dataset. In embodiments, the training dataset may also include associated recombination configuration data 712 for forming a training dataset, where each data point and/or associated recombination configuration may include various labels or classifications of one or more types of useful information. This data may be processed to generate one or multiple training datasets 636 for training of one or more machine learning models.

In one embodiment, generating one or more training datasets 636 includes gathering one or more process result measurements (e.g., metrology data) of processed substrates processed in chambers with varying recombination configurations disposed on the chamber walls of the associated chambers.

To effectuate training, processing logic inputs the training dataset(s) 736 into one or more untrained machine learning models. Prior to inputting a first input into a machine learning model, the machine learning model may be initialized. Processing logic trains the untrained machine learning model(s) based on the training dataset(s) to generate one or more trained machine learning models that perform various operations as set forth above.

Training may be performed by inputting one or more of the process result data 710 and recombination configuration data 712 into the machine learning model one at a time. In some embodiments, the training of the machine learning model includes tuning the model to receive process result data 710 (e.g., process result profiles, thickness profiles of processed substrates) and output a recombination configuration prediction (e.g., one or more materials having a set of recombination coefficients and a corresponding location where the corresponding one or more materials are to be disposed within a processing chamber). The machine learning model processes the input to generate an output. An artificial neural network includes an input layer that consists of values in a data point. The next layer is called a hidden layer, and nodes at the hidden layer each receive one or more of the input values. Each node contains parameters (e.g., weights) to apply to the input values. Each node therefore essentially inputs the input values into a multivariate function (e.g., a non-linear mathematical transformation) to produce an output value. A next layer may be another hidden layer or an output layer. In either case, the nodes at the next layer receive the output values from the nodes at the previous layer, and each node applies weights to those values and then generates its own output value. This may be performed at each layer. A final layer is the output layer, where there is one node for each class, prediction and/or output that the machine learning model can produce.

Accordingly, the output may include one or more predictions or inferences. For example, an output prediction or inference may include a determined recombination configuration. Processing logic may cause a substrate to be process using the recombination configuration and receive an updated thickness profile. Processing logic may compare the updated thickness profile against a target thickness profile and determine whether a threshold criterion is met (e.g., thickness values measured across a surface of the wafer fall within a target threshold value window). Processing logic determines an error (i.e., a classification error) based on the differences between the updated thickness profile and the target thickness profile. Processing logic adjusts weights of one or more nodes in the machine learning model based on the error. An error term or delta may be determined for each node in the artificial neural network. Based on this error, the artificial neural network adjusts one or more of its parameters for one or more of its nodes (the weights for one or more inputs of a node). Parameters may be updated in a back propagation manner, such that nodes at a highest layer are updated first, followed by nodes at a next layer, and so on. An artificial neural network contains multiple layers of “neurons”, where each layer receives as input values from neurons at a previous layer. The parameters for each neuron include weights associated with the values that are received from each of the neurons at a previous layer. Accordingly, adjusting the parameters may include adjusting the weights assigned to each of the inputs for one or more neurons at one or more layers in the artificial neural network.

Once the model parameters have been optimized, model validation may be performed to determine whether the model has improved and to determine a current accuracy of the deep learning model. After one or more rounds of training, processing logic may determine whether a stopping criterion has been met. A stopping criterion may be a target level of accuracy, a target number of processed images from the training dataset, a target amount of change to parameters over one or more previous data points, a combination thereof and/or other criteria. In one embodiment, the stopping criteria is met when at least a minimum number of data points have been processed and at least a threshold accuracy is achieved. The threshold accuracy may be, for example, 70%, 80% or 90% accuracy. In one embodiment, the stopping criteria are met if accuracy of the machine learning model has stopped improving. If the stopping criterion has not been met, further training is performed. If the stopping criterion has been met, training may be complete. Once the machine learning model is trained, a reserved portion of the training dataset may be used to test the model.

As an example, in one embodiment, a machine learning model (e.g., recombination configuration predictor 767) is trained to determine recombination configurations (e.g., materials with sets of recombination coefficients and locations the materials are to be disposed within a chamber to process a substrate to meet threshold criteria (e.g., process uniformity requirements)). A similar process may be performed to train machine learning models to perform other tasks such as those set forth above. A set of many (e.g., thousands to millions) process results profiles (e.g., thickness profiles) may be collected and recombination configurations (e.g., surface material configurations within a process chamber) may be determined.

Once one or more trained machine learning models 738 are generated, they may be stored in model storage 745, and may be added to a recombination configuration application. Recombination configuration application may then use the one or more trained ML models 738 as well as additional processing logic to implement an automatic mode, in which user manual input of information is minimized or even eliminated in some instances.

For model application workflow 717, according to one embodiment, input data 862 may be input into recombination configuration predictor 767, which may include a trained neural network. Based on the input data 762, recombination configuration predictor 767 outputs information indicating and locations to dispose the materials within a process chamber (e.g., recombination configuration data 769).

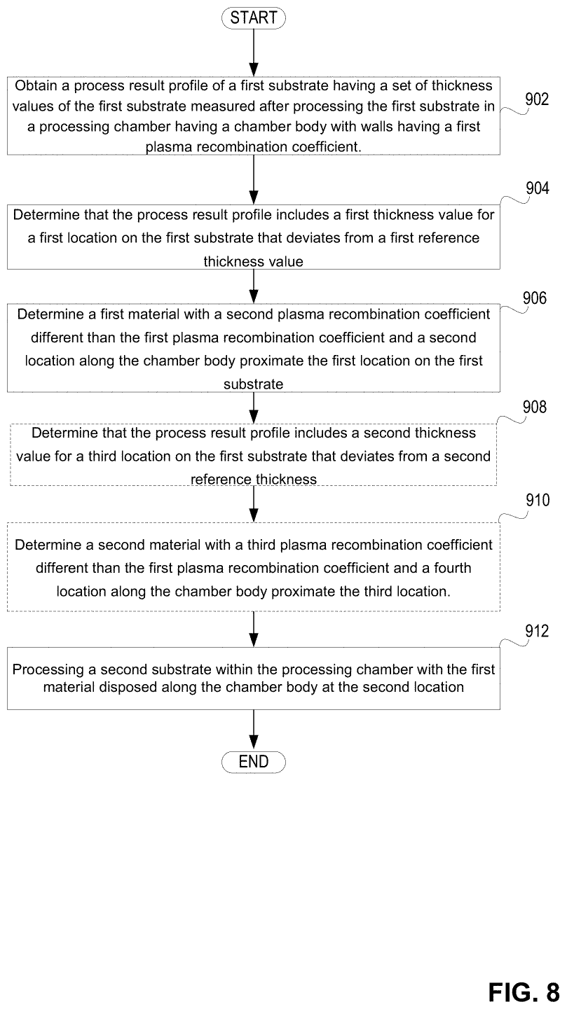

FIG. 8 depicts a flow diagram of one example method 800 for predicting a recombination configuration for a processing chamber, in accordance with some implementations of the present disclosure. Method 800 is performed by processing logic that may comprise hardware (e.g., circuitry, dedicated logic, etc.), software (such as is run on a general purpose computer system or a dedicated machine) or any combination thereof. In one implementation, the method is performed using server 612 and the model 690 of FIG. 6, while in some other implementations, one or more blocks of FIG. 8 may be performed by one or more other machines not depicted in the figures.

At block 802, processing logic obtains a process result profile of a first substrate having a set of thickness values of the first substrate measured after processing the first substrate in a processing chamber having a chamber body with wall having a first material with a first set of plasma recombination coefficients. The processing chamber may include one or more features and/or aspects of processing system 200, 300 of FIG. 2A and FIG. 3A. The processing result profile may include one or more features and/or aspects of process result profile 250, 350 of FIGS. 2B and 3B.

At block 804, processing logic determines that the process result profile includes a first thickness value for a first location on the first substrate that deviates from a first reference thickness value. The reference thickness value may be associated with process result criteria (e.g., process uniformity requirements). For example, the reference thickness may be an average thickness or a process control limit associated with processing chamber.

At block 806, processing logic determine a first material with a second set of plasma recombination coefficients that are different than the first set of plasma recombination coefficients and a second location along the chamber body proximate the first location on the first substrate. The processing logic may further determine a configuration for the first material. For example, the first material may be disposed within the processing chamber in concentric rings or disks.

In another example, the first material may be disposed along the walls of the interior volume of the processing at a location proximate a central region of a substrate disposed within the processing chamber and can affect the process result of substrate at and/or near the center of the substrate. For example, in embodiments where the first material has one or more higher recombination coefficients than the materials of the walls of the chamber, the addition of the first material can raise the process result near the center of the substrate processed within the processing chamber. In another example, in embodiments where the first material has one or more lower recombination coefficients than materials of the walls of the chamber, the addition of the first material lowers the process result near the center of the substrate when processed in the processing chamber.

In some embodiments the surface materials may be moveable within the process chamber. For example, the processing chamber may include an actuator that couples to the first material. The first material may be coupled to the walls of the processing chamber and be disposed a distance from the walls. The actuator may be leveraged to alter the distance between the first material(s) and the walls. For example, the first material may be coupled to a translatable platform affixed (e.g., fastened and/or adhered) to the walls. The actuator may translate the surface materials to be closer or further away from the substrate.

In some embodiments, the first material may be deployed within the processing chamber using liners and/or films. In some embodiments, the first material may be disposed within the processing chamber as a foldable diaphragm structure. The foldable diaphragm structure may include multiple movable intercepting panels or leaves that can alters its shape (e.g., increase/decrease exposed surface area) resulting in a larger or smaller influence on a process result of a region proximate the foldable diaphragm. In some embodiments, the processing chamber includes a mechanism (e.g., translation plate, rotating plate, etc.) for altering a position of the foldable diaphragm structure within the processing chamber.

In some embodiments, the processing chamber includes mechanisms for heating and/or cooling the first material within the processing chamber. Method 800 may further include heating and/or cooling of the first material. The resulting heating and/or cooling may modify the one or more recombination coefficients of the first material. The heating and/or cooling may extend a usable range of recombination coefficients (e.g., without changing the first material).

In some embodiments, the processing logic further includes using the first process result profile as input to a machine learning model. The method further includes obtaining one or more outputs of the machine learning model. The one or more outputs indicating the first material and the second location. The machine learning model may include one or more features and/or aspects of model 690 of FIG. 6.

At block 808, processing logic, optionally, determines that the process result profile includes a second thickness value for a third location on the first substrate that deviates from a second reference thickness. At block 910, processing logic, optionally, determines a second material with a third set of plasma recombination coefficients different than the first set of plasma recombination coefficients and a fourth location. In some embodiments one or more plasma recombination coefficients of the second set are greater than the corresponding plasma recombination coefficients of the first set and plasma recombination coefficients of the third set. Plasma recombination coefficients of the third set are less than corresponding plasma recombination coefficients of the second set.

At block 812, the method 800 includes processing a second substrate within the processing chamber with the first material disposed along the chamber body at the second location. In some embodiments, various combinations of materials with varying sets of plasma recombination coefficients may be disposed at various points within a processing chamber along a chamber body proximate various regions of a substrate to affect a process result of a substrate processed within the chamber with the associated surface material configuration.

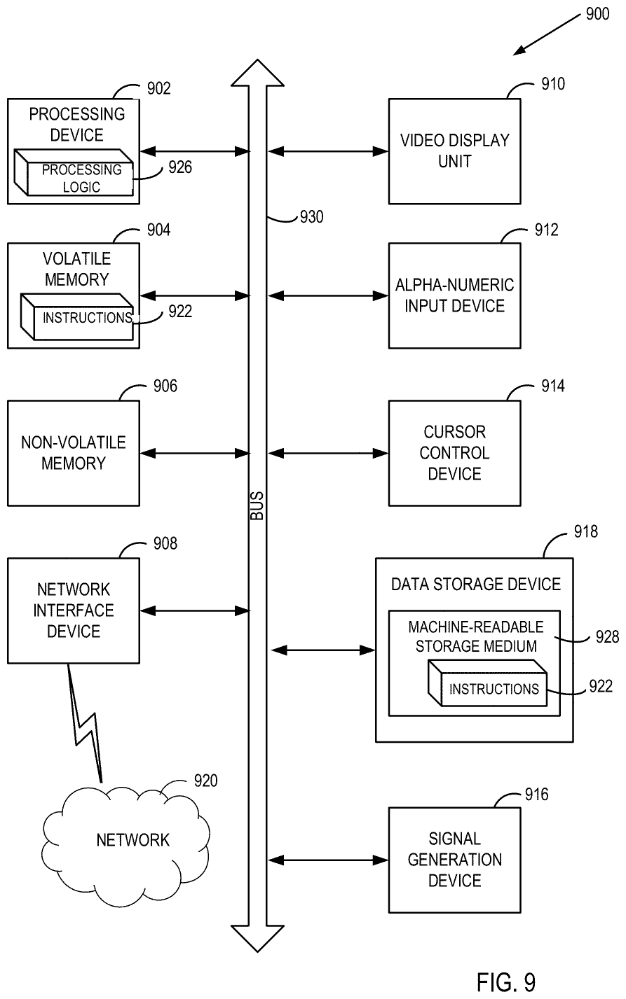

FIG. 9 depicts a block diagram of an example computing device 900 capable of plasma delivery and/or processing, operating in accordance with one or more aspects of the disclosure. In various illustrative examples, various components of the computing device 900 may represent various components of computing device (e.g. modeling system 610 of FIG. 6), the training engine, validation engine, and/or the testing engine described in association with FIG. 6.

Example computing device 900 may be connected to other computer devices in a LAN, an intranet, an extranet, and/or the Internet. Computing device 900 may operate in the capacity of a server in a client-server network environment. Computing device 900 may be a personal computer (PC), a set-top box (STB), a server, a network router, switch or bridge, or any device capable of executing a set of instructions (sequential or otherwise) that specify actions to be taken by that device. Further, while only a single example computing device is illustrated, the term “computer” shall also be taken to include any collection of computers that individually or jointly execute a set (or multiple sets) of instructions to perform any one or more of the methods discussed herein.

Example computing device 900 may include a processing device 902 (also referred to as a processor or CPU), a main memory 904 (e.g., read-only memory (ROM), flash memory, dynamic random access memory (DRAM) such as synchronous DRAM (SDRAM), etc.), a static memory 906 (e.g., flash memory, static random access memory (SRAM), etc.), and a secondary memory (e.g., a data storage device 918), which may communicate with each other via a bus 930.

Processing device 902 represents one or more general-purpose processing devices such as a microprocessor, central processing unit, or the like. More particularly, processing device 902 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 902 may also be one or more special-purpose processing devices such as an application specific integrated circuit (ASIC), a field programmable gate array (FPGA), a digital signal processor (DSP), network processor, or the like. In accordance with one or more aspects of the disclosure, processing device 902 may be configured to execute instructions implementing methods 800 illustrated in FIG. 8.

Example computing device 900 may further comprise a network interface device 908, which may be communicatively coupled to a network 920. Example computing device 900 may further comprise a video display 910 (e.g., a liquid crystal display (LCD), a touch screen, or a cathode ray tube (CRT)), an alphanumeric input device 912 (e.g., a keyboard), a cursor control device 914 (e.g., a mouse), and an acoustic signal generation device 916 (e.g., a speaker).

Data storage device 918 may include a machine-readable storage medium (or, more specifically, a non-transitory machine-readable storage medium) 928 on which is stored one or more sets of executable instructions 922. In accordance with one or more aspects of the disclosure, executable instructions 922 may comprise executable instructions associated with executing methods 800 illustrated in FIG. 8.

Executable instructions 922 may also reside, completely or at least partially, within main memory 904 and/or within processing device 902 during execution thereof by example computing device 900, main memory 904 and processing device 902 also constituting computer-readable storage media. Executable instructions 922 may further be transmitted or received over a network via network interface device 908.

While the computer-readable storage medium 928 is shown in FIG. 9 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, compact disc read only memory (CD-ROMs), and magnetic-optical disks, read-only memories (ROMs), random access memories (RAMs), erasable programmable read-only memory (EPROMs), electrically erasable programmable read-only memory (EEPROMs), magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the disclosure is not limited to any particular programming language. It will be appreciated that a variety of programming languages may be used to implement the teachings of the disclosure.

The preceding description sets forth numerous specific details such as examples of specific systems, components, methods, and so forth, in order to provide a good understanding of several embodiments of the disclosure. It will be apparent to one skilled in the art, however, that at least some embodiments of the disclosure may be practiced without these specific details. In other instances, well-known components or methods are not described in detail or are presented in simple block diagram format in order to avoid unnecessarily obscuring the disclosure. Thus, the specific details set forth are merely exemplary. Particular implementations may vary from these exemplary details and still be contemplated to be within the scope of the disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.” When the term “about” or “approximately” is used herein, this is intended to mean that the nominal value presented is precise within ±10%.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

1. A plasma processing system, comprising:
a processing chamber comprising a chamber body having walls with a first material enclosing an interior volume;
a plasma source configured to expose a substrate disposed within the processing chamber to plasma related fluxes, wherein the first material has a first set of recombination coefficients associated with the plasma related fluxes; and
a second material disposed along a first region of the chamber body, the first material having a second set of plasma recombination coefficients associated with the plasma related fluxes, wherein the second set of plasma recombination coefficients is different from the first set of plasma recombination coefficients.

2. The plasma processing system of claim 1, further comprising:
a third material disposed along a second region of the chamber body, the third material having a third set of plasma recombination coefficients associated with the plasma related fluxes, wherein the second set of plasma recombination coefficients are different from the first set of plasma recombination coefficients and the second set of plasma recombination coefficients.

3. The plasma processing system of claim 2, wherein:
one or more of the plasma recombination coefficients of the second set are greater than corresponding plasma recombination coefficients of the first set; and
one or more of the plasma recombination coefficients of the third set are less than corresponding plasma recombination coefficients of the first set.

4. The plasma processing system of claim 1, wherein:
the chamber body further comprises a support structure to support the substrate; and
the second material is disposed along a surface of the support structure.

5. The plasma processing system of claim 1, wherein the second material is disposed along the first region in a plurality of concentric rings.

6. The plasma processing system of claim 1, wherein the wall comprises quartz and the first material comprises at least one of: a borosilicate based material, Titanium, or stainless steel.

7. The plasma processing system of claim 1, further comprising an actuator coupled to the second material, the actuator configured to vary a first distance between the second material and the chamber body.

8. The plasma processing system of claim 1, wherein at least one of the first set of plasma recombination coefficients or at least one of the second set of plasma recombination coefficients is associated with silicon nitridation occurring within the processing chamber.

9. The plasma processing system of claim 1, wherein:
the processing chamber comprises an annular plasma injection site formed between a first radius and a second radius of a first surface of the chamber body, the annular plasma injection site is configured to deliver plasma from the plasma source to the interior volume of the processing chamber; and
the first material is disposed along the first surface of the chamber body within the first radius.

10. A method, comprising:
obtaining a process result profile of a first substrate, the process result profile comprising a plurality of thickness values of the first substrate measured after processing the first substrate in a processing chamber having a chamber body with walls comprising a first material having a first set plasma recombination coefficients; and
determining that the process result profile comprises a first thickness value for a first location on the first substrate that deviates from a first reference thickness value;
responsive to determining that the process result profile comprises the first thickness value that deviates from the first reference thickness value, determining a second material having a second set plasma recombination coefficients different than the first set of plasma recombination coefficients and a second location along the chamber body proximate the first location on the first substrate; and
processing a second substrate within the processing chamber with the second material disposed along the chamber body at the second location.

11. The method of claim 10, further comprising:
determining that the process result profile comprises a second thickness value for a third location on the first substrate that deviates from a second reference thickness value; and
responsive to determining that the process result profile comprises the second thickness value that deviates from the second reference thickness value, determining a second material with a third set of plasma recombination coefficients different than the first set of plasma recombination coefficients and a fourth location along the chamber body proximate the third location, wherein the second substrate is processed with the second material disposed along the chamber body at the fourth location.

12. The method of claim 11, wherein:
one or more of plasma recombination coefficients of the second set are greater than corresponding plasma recombination coefficients of the first set; and
one or more of the plasma recombination coefficient of the third set are less than corresponding plasma recombination coefficient of the first set.

13. The method of claim 10, wherein the second material is disposed along the chamber body in a configuration having concentric rings.

14. The method of claim 10, further comprising:
causing operation of an actuator to vary a first distance between the second material and the chamber body to position the second material in the second location.

15. The method of claim 10, further comprising:
using the process result profile as input to a machine learning model; and
obtaining one or more outputs of the machine learning model, the one or more outputs indicating the second material and the second location.

16. The method of claim 10, further comprising causing heating or cooling of the second material to change the second plasma recombination coefficient to a third plasma recombination coefficient.

17. A processing chamber apparatus, comprising:
a chamber body having walls with a first material enclosing an interior volume, wherein the first material has a first set of plasma recombination coefficients;
a second material disposed along a first region of the chamber body, the first material having a second set of plasma recombination coefficients that are different than the first set of plasma recombination coefficients; and
a third material disposed along a second region of the chamber body, the third material having a third set of plasma recombination coefficients that are different than the first set of plasma recombination coefficients and the second set of plasma recombination coefficients.

18. The processing chamber apparatus of claim 17, wherein:
one or more of the plasma recombination coefficient of the second set are greater than corresponding plasma recombination coefficient of the first set; and
one or more of the plasma recombination coefficient of the third set are less than corresponding plasma recombination coefficient of the first set.

19. The processing chamber apparatus of claim 17, wherein:
the chamber body further comprises a support structure to support a substrate; and
the second material is disposed along a surface of the support structure.

20. The processing chamber apparatus of claim 17, wherein at least one of the first set of plasma recombination coefficient or the second set of plasma recombination coefficients is associated with silicon nitridation occurring within the processing chamber apparatus.
